(19) United States
(12) Patent Application Publication
(10) Pub. No.: US 2006/0022304 A1
(43) Pub. Date: Feb. 2, 2006

(54) Dielectric structure

(75) Inventor: Maria Anna Rzeznik, Framingham, MA (US)

Correspondence Address: S. Matthew Cairns;Rohm and Haas Electronic Materials LLC, 455 Forest Street, Marlborough, MA, 01752, US

(73) Assignee: Rohm and Haas Electronic Materials LLC, Marlborough, MA (US)

(21) Appl. No.: 11/191,486

(22) Filed: Jul. 28, 2005

Related U.S. Application Data
(60) Provisional application No. 60/592,259, filed on Jul. 29, 2004.

(51) Int. Cl. H01L 29/00; H01L 21/20

(52) U.S. Cl. 257/532; 438/240; 438/763; 438/393

(57) ABSTRACT

Dielectric structures particularly suitable for use in capacitors having a layer of a dielectric material including a dopant that provides a positive topography are disclosed. Methods of forming such dielectric structures are also disclosed. Such dielectric structures show increased adhesion of subsequently applied conductive layers.

The present invention relates generally to the field of dielectric structures. In particular, the present invention relates to the field of dielectric structures suitable for use in capacitor manufacture.

Laminated printed circuit boards, as well as multichip modules, serve as support substrates for electronic components, such as integrated circuits, capacitors, resistors, inductors, and other components. Conventionally, discrete passive components, e.g. resistors, capacitors and inductors, are surface mounted to the printed circuit boards. Such surface mounted passive components can occupy up to 60% or greater of the real estate of a printed circuit board surface, thus limiting the space available for the mounting of active components, such as integrated circuits. The removal of passive components from the printed circuit board surface allows for increased density of active components, further miniaturization of the printed circuit board, increased computing power, reduced system noise and reduced noise sensitivity due to shortened leads.

Removal of discrete passive components from the printed circuit board surface can be achieved by embedding the passive components within the laminated printed circuit board structure. Embedded capacitance has been discussed in the context of capacitive planes providing non-individual or “shared” capacitance. Capacitive planes consist of two laminated metal sheets insulated by a polymer based dielectric layer. Shared capacitance requires the timed use of the capacitance by other components. Such shared capacitance fails to adequately address the need for embedded capacitors that still function as discrete components.

Discrete embedded capacitors using polymeric materials as the capacitor dielectric are known. These materials suffer from having a relatively low dielectric constant. Filling such polymeric material with a high-dielectric constant material, such as certain ceramics, has been suggested as a way to increase the capacitance density of the material. However, such materials still do not possess a sufficiently high capacitance density needed in advanced printed circuit boards. The capacitance of a capacitor is defined by the area of the smaller of the two electrodes on either side of the dielectric material.

Recently, embedded capacitors containing a high dielectric constant material, such as a ceramic or metal oxide, have been suggested. One problem with using such ceramics or metal oxides as the capacitor dielectric material is that they may be difficult to metallize, i.e., to fabricate an electrode on, using techniques conventionally used in the printed circuit board industry. U.S. Pat. No. 6,661,642 (Allen et al.) discloses a capacitor containing a multilayer dielectric material including a first and a second dielectric layer, where the first dielectric layer includes a plating dopant in an amount sufficient to promote plating of a conductive layer on the multilayer dielectric. Such plating dopants may adversely affect the overall dielectric constant and, therefore, the capacitance of the multilayer dielectric material. U.S. Pat. No. 6,819,540 (Allen et al.) discloses a capacitor containing a multilayer dielectric material including a first and a second dielectric layer, where the first dielectric layer is textured, i.e., has a rough surface. Such first dielectric layer is textured by the removal of certain pore forming materials, which produces a surface having a “negative” topography. By “negative topography” is meant a rough surface in a material formed by the removal of something, thus making the surface rough (or textured) by the formation of voids in the material. As the pore forming materials are removed, pores or voids in the dielectric material are formed which typically contain air, which may result in an overall lowering of the dielectric constant of the multilayer dielectric material, which in turn lowers the capacitance of the capacitor.

There is a need for capacitors, particularly embedded capacitors, having high capacitance density that are easier to fabricate electrodes on than conventional high capacitance density material. There is also a need for improving the adhesion of electrodes to ceramic dielectric capacitors used in embedded capacitor products.

It has been surprisingly found that the adhesion of plated electrode layers to high dielectric constant material can be improved by providing a dopant in the dielectric material, where the dopant provides positive topography at the surface of the high dielectric constant material layer. A dielectric material having a “positive topography” means a dielectric material having a rough surface formed by the addition of another material such that the surface contains protrusions. As used herein, “protrusion” refers to any feature that protrudes from the plane of the surface of the dielectric material.

The present invention provides a multilayer dielectric structure having a first dielectric layer and a second dielectric layer, wherein the first dielectric layer includes a dopant. Typically, the first dielectric layer also includes a dielectric material having a dielectric constant ≧10. In one embodiment, the dopant has a dielectric constant greater than or equal to the dielectric constant of the bulk dielectric material. In another embodiment, the dopant has a dielectric constant substantially similar to the bulk dielectric material. In a further embodiment, the dopant and the bulk dielectric material have the same composition. The dopant-containing dielectric material layer has a positive topography. Dielectric structures having a dielectric material layer including a dopant in an amount sufficient to provide a plated conductive layer on the surface of the dielectric layer having good adhesion to the dielectric material are also contemplated by this invention. Capacitors containing such dielectric structures are further contemplated by this invention.

In another embodiment, the present invention provides a dielectric structure including a dielectric layer disposed on a substrate, such as a conductive layer, wherein the dielectric layer includes a dopant-containing region and a non-dopant-containing region, the dopant-containing region forming a positive topography at a surface of the dielectric structure. Further, the present invention provides a capacitor including a first electrode, a second electrode and a dielectric structure disposed between the electrodes, wherein the dielectric structure includes a dielectric material including a dopant-containing region and a non-dopant-containing region, wherein the dopant-containing region is adjacent the first electrode. Alternatively, the dopant-containing region may be adjacent the second electrode. The dopant is itself a dielectric material.

The present invention also provides a method of improving the adhesion of catalytic and plated electrodes to a dielectric layer including the steps of disposing on a substrate a dielectric structure having a surface having a positive topography, the dielectric structure including a dielectric material having a dielectric dopant-containing region and a non-dopant-containing region, the dielectric material having a dielectric constant ≧10, and plating a conductive layer on the surface of the dielectric structure. The dopant-containing region forms the surface of the dielectric structure having the positive topography. Such method is also used in the manufacture of capacitors. In such capacitors, the substrate is typically a bottom conductive layer. Typically, the dielectric material is a ceramic. More typically, the dielectric material and the dopant are both ceramics.

Further provided by the present invention is a method of forming the dielectric structure described above including the steps of disposing a layer of a first dielectric material on a substrate, disposing a layer of a dielectric dopant-containing dielectric material on the first dielectric material, and annealing the layers of dielectric materials to form the dielectric structure.

The present invention provides an electronic device, such as a printed circuit board, including the capacitor described above. In particular, the present invention provides a printed circuit board including an embedded capacitance material, wherein the embedded capacitance material includes a dielectric structure including a dielectric material having a dopant-containing region and a non-dopant-containing region wherein the dopant-containing region forms a surface of the dielectric structure. Typically, the first dielectric layer also includes a dielectric material having a dielectric constant ≧10. A method of manufacturing the printed circuit board described above is also contemplated herein.

Further provided by the present invention are chip capacitors, multichip modules and other surface mount capacitors containing the dielectric structure described above.

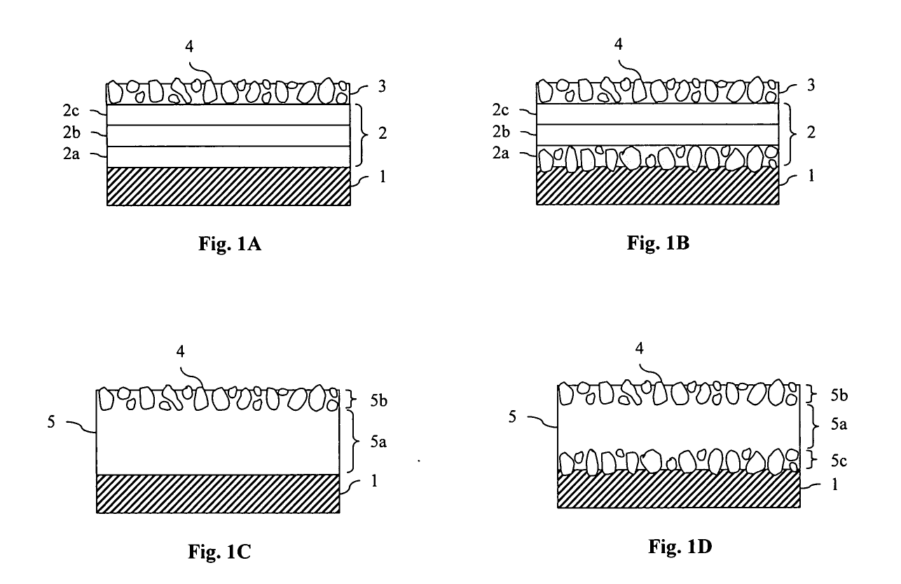

FIGS. 1A-D illustrate a dielectric structure according to the invention, not to scale.

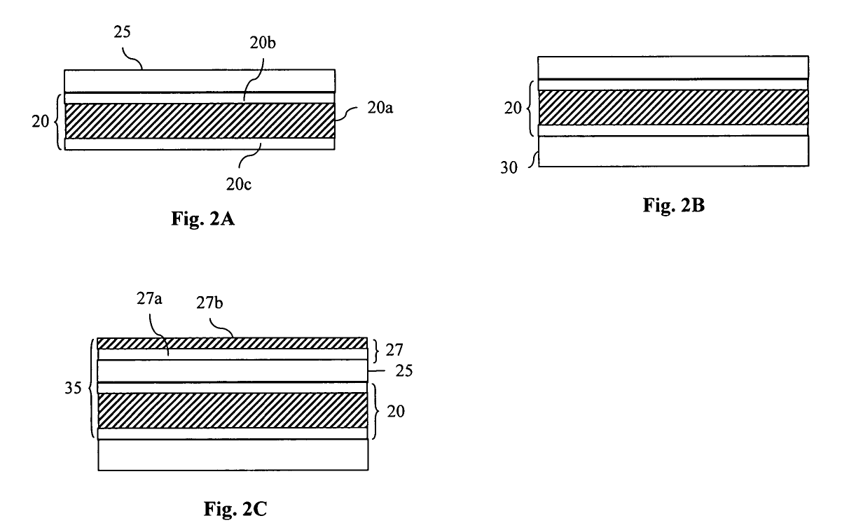

FIGS. 2A-C illustrate one process of forming a capacitor of the invention.

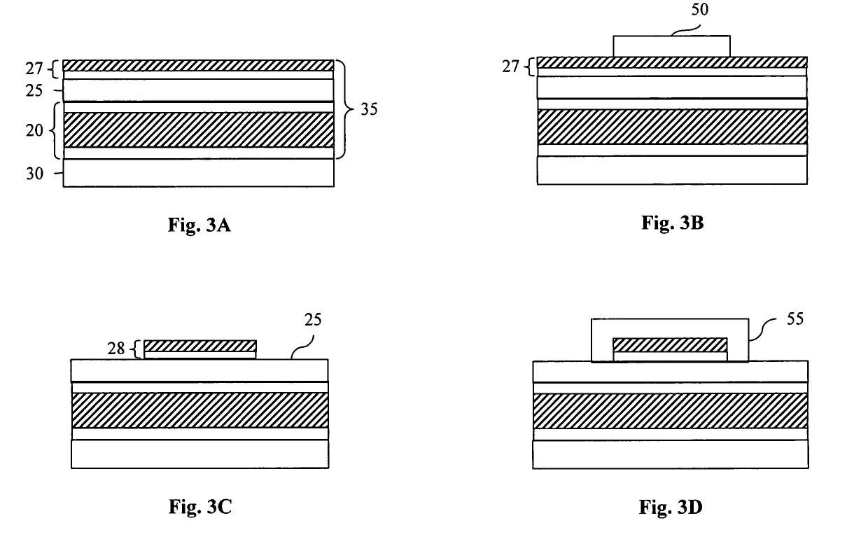

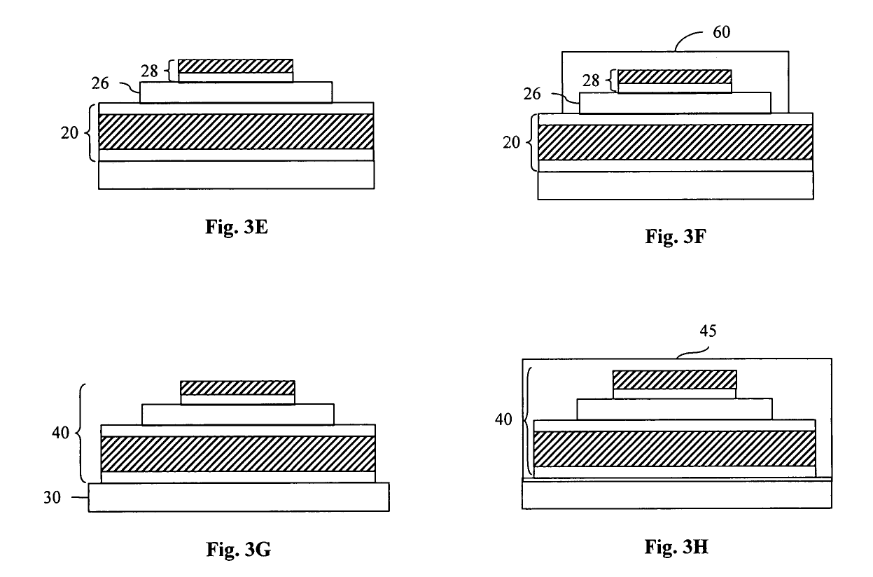

FIGS. 3A-H illustrate one process of patterning a capacitor of the invention.

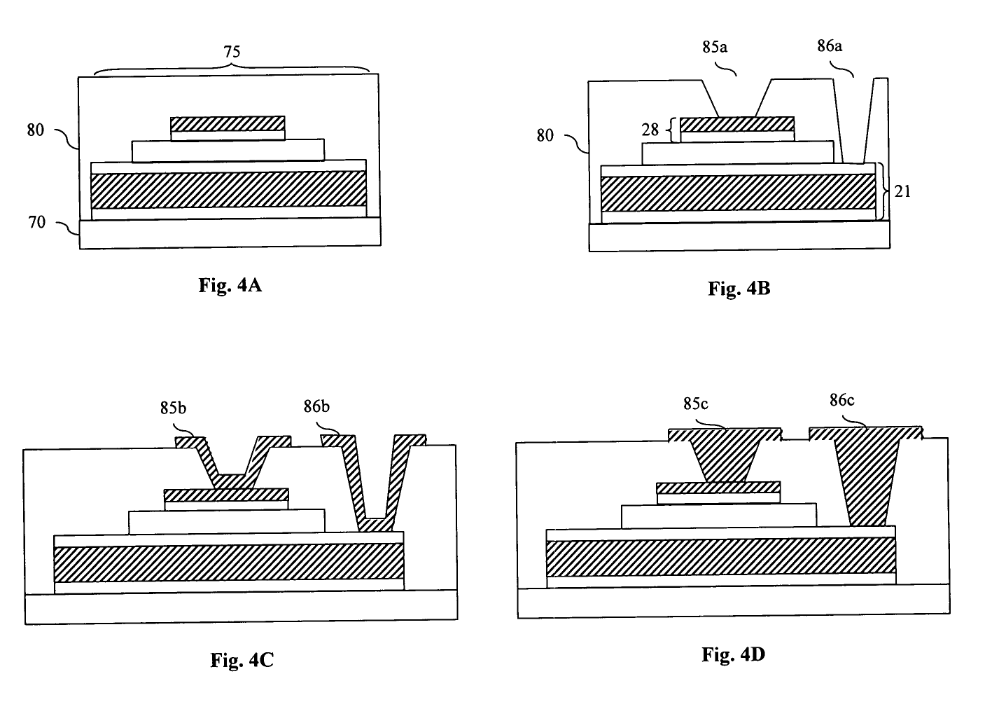

FIGS. 4A-D illustrate one process of forming an embedded capacitor according to the invention.

In the figures, like reference numerals refer to like elements.

As used throughout this specification, the following abbreviations shall have the following meanings: ° C.=degrees Centigrade; rpm=revolutions per minute; mol=moles; hr=hours; min=minute; sec=second; nm=nanometers; μm=microns=micrometers; cm=centimeters; in.=inches; nF=nanofarads; and wt %=percent by weight.

The terms “printed wiring board” and “printed circuit board” are used interchangeably throughout this specification. “Depositing” and “plating” are used interchangeably throughout this specification and include both electroless plating and electrolytic plating. “Multilayer” refers to two or more layers. The term “dielectric structure” refers to a layer or layers of dielectric material used as the dielectric in a capacitor. “Alkyl” refers to linear, branched and cyclic alkyl. The terms “a” and “an” refer to the singular and the plural.

All percentages are by weight, unless otherwise noted. All numerical ranges are inclusive and combinable in any order, except where it is clear that such numerical ranges are constrained to add up to 100%.

The present invention provides a dielectric structure including a layer of a dielectric material which includes a dopant. Dopants useful in the present invention are dielectric materials and may be any which function as a capacitor dielectric. As used herein, “dopant” refers to any dielectric material present in a bulk dielectric material that provides a positive topography to a surface of the bulk dielectric material. The term “bulk dielectric material” refers to the dielectric material used to form the dielectric material layer and which contains the dopant. Such dielectric structures are particularly suitable for the fabrication of capacitors, such as for the fabrication of capacitors that can be embedded within a laminated printed circuit board. Such capacitors contain a pair of electrodes (conductive layers or metal layers) on opposite surfaces of and in intimate contact with the dielectric structure. Capacitance density is determined by the electrode surface area, the dielectric constant of the dielectric structure and the thickness of the capacitor. The present invention provides an increase in electrode surface area for a given geometrical area without increasing the likelihood of short circuits.

Typically, the dielectric material useful in the present dielectric structures is any that is suitable for use as capacitor dielectric. A wide variety of dielectric material may be employed, depending upon the design requirements of the capacitor. Suitable “low” dielectric constant material includes polymers having a dielectric constant of 2 to <10. Particularly useful low dielectric constant materials are those having a dielectric constant of 3 to 9. “Medium” dielectric constant refers to a dielectric constant ≧10, and preferably >10. In one embodiment, the dielectric material has a “high” dielectric constant, such as ≧50, and preferably ≧100. In another embodiment, the dielectric material has a dielectric constant ≧10, typically ≧25, and more typically ≧50.

Typically, when a dielectric structure contains a single layer of dielectric material, such dielectric material has a dielectric constant >10 and includes a dopant. Such single layer of dielectric material has a dopant-containing region adjacent an electrode. When the dielectric structure contains multiple layers of dielectric materials, a dielectric layer adjacent an electrode, i.e. in intimate contact with the electrode, contains a dopant. Such topmost dielectric material may be a material having any of a variety of dielectric constants.

A wide variety of dielectric materials may suitably be used. Exemplary low dielectric constant materials include, without limitation, polymers such as epoxies, polyimides polyurethanes, polyarylenes including polyarylene ethers, polysulfones, polysulfides, fluorinated polyimides, and fluorinated polyarylenes.

Typically, the dielectric material is chosen from medium and high dielectric constant materials, as well as mixtures thereof. Exemplary medium and high dielectric constant materials include, but are not limited to, ceramics, metal oxides and combinations thereof. Suitable ceramics and metal oxides include, without limitation, titanium dioxide (“TiO₂”), tantalum oxides such as Ta₂O₅, barium-titanates having the formula BaₐTi_{b}O_{c} wherein a and b are independently from 0.5 to 1.25 and c is 2.5 to 5, strontium-titanates such as SrTiO₃, barium-strontium-titanates such as those having the formula BaₓSr_{y}Ti_{z}O_{q} where x and y are independently chosen from 0 to 1.25, z is 0.8 to 1.5 and q is 2.5 to 5, lead-zirconium-titanates such as PbZr_{y}Ti_{1-y}O₃, the series of doped lead-zirconium-titanates having the formula (PbₓM₁₋ₓ)(Zr_{y}Ti_{1-y})O₃ where M is any of a variety of metals such as alkaline earth metals and transition metals such as niobium and lanthanum, where x denotes lead content and y is the zirconium content of the oxide, lithium-niobium oxides such as LiNbO₃, lead-magnesium-titanates such as (PbₓMg₁₋ₓ)TiO₃, and lead-magnesium-niobium oxides such as (PbₓMg₁₋ₓ)NbO₃, and lead-strontium-titanates (PbₓSr₁₋ₓ)TiO₃. When the capacitor dielectric material includes BaₐTi_{b}O_{c}, it is preferred that a and b are both 1 and c is 3, i.e. BaTiO₃. Other suitable dielectric materials include, but are not limited to: silsesquioxanes such as alkyl silsesquioxanes, aryl silsesquioxanes, hydridosilsesquioxanes and mixtures thereof; silica; and siloxanes; including mixtures of any of the foregoing. Suitable alkyl silsesquioxanes include (C₁-C₁₀)alkyl silsesquioxanes such as methyl silsesquioxanes, ethyl silsesquioxanes, propyl silsesquioxanes, and butyl silsesquioxanes. It is preferred that the dielectric material includes a ceramic, metal oxide or mixtures thereof. Ceramics are particularly useful dielectric materials in the present invention. Such ceramic dielectric materials may be used in a variety of crystal structures including, without limitation, perovskites (ABO₃), pyrochlores (A₂B₂O₇), rutile and other structural polymorphs that have suitable electrical properties for use as a capacitor dielectric.

When a polymer/ceramic or polymer/metal oxide composite capacitor dielectric material is used, the ceramic or metal oxide material may be blended as a powder with the polymer. When the ceramic or metal oxide is used without a polymer, such ceramic or metal oxide may be deposited by a variety of means, such as, but not limited to, sol-gel, physical and/or reactive evaporation, sputtering, laser-based deposition techniques, chemical vapor deposition (“CVD”), combustion chemical vapor deposition (“CCVD”), controlled atmosphere chemical vapor deposition (“CACCVD”), hydride vapor phase deposition, liquid phase epitaxy, and electro-epitaxy. Preferably, such ceramic or metal oxide material is deposited by using sol-gel techniques.

In such sol-gel processes, as exemplified herein by the deposition of a barium strontium titanate (“BST”) capacitor dielectric, a solution of titanium alkoxide, barium precursor and strontium precursor are reacted at the desired stoichiometry and controllably hydrolyzed with a solvent/water solution. A thin, adherent film of the hydrolyzed solution (or “sol”) is then applied to the substrate by a suitable method, such as dip-coating, spin-coating at 1,000 to 3,000 rpm or meniscus coating. Meniscus coating is a particularly suitable technique.

In meniscus coating, the substrate is positioned on a vacuum chuck. The chuck is then inverted to place the substrate in a coating position over an applicator bar. The applicator bar is a tube having a closed end, an open end and a slot running along a length of the tube, the slot communicating with the interior of the tube, the applicator bar being disposed horizontally such that the slot is at an upper surface of the tube. Material, such as a sol, to be coated is provided to the applicator bar through the open end. In one embodiment, the material is pumped into the tube through the open end. In another embodiment, the applicator bar is disposed within a reservoir. The sol flows through the tube and exits the tube through the slot, forming a meniscus. The substrate is positioned over the applicator bar such that a surface of the substrate to be coated contacts the meniscus of the sol. The applicator bar moves beneath the substrate to provide a coating of the sol on the substrate surface. Alternatively, a web of substrate to be coated, such as a roll of metal foil, such as copper foil, may be passed over a moving, or in the alternative a stationary, applicator bar to coat the substrate surface.

Alternatively, the substrate to be coated with the capacitor dielectric may be dipped into the sol at an average speed of 2 to 12 cm/min (1 to 5 in./min) and preferably from 2 to 8 cm/min.

Following coating, the films are heated at a temperature of 200 to 600° C. for about 5 to 10 minutes to volatilize the organic species and to render the dried “gel” film. Other suitable temperatures and times may be used, the selection of which are within the ability of those skilled in the art. Multiple coatings may be required for increased film thicknesses. While the majority of the organic matter and water is removed from the films by heating at 500° C.; the BST film is still only partially crystalline.

The thickness of a film or layer deposited from a sol-gel process depends upon the rotation rate (spin-coating), coating speed (e.g. meniscus coating) and the viscosity of the solution. Typically, the thickness of the layer is 25 nm or greater, more typically 50 nm or greater, and still more typically 100 nm or greater. A particularly useful thickness is in the range of 25 to 700 nm and more particularly from 50 to 250 mm. The total thickness of a capacitor dielectric structure is determined by the sum of the thicknesses of each layer in the dielectric structure.

The film is then annealed for a period of time to provide the desired crystalline structure. For example, such films may be annealed at the temperature range of 600 to 800° C. Typically, the duration of annealing is about 15 minutes, however a variety of annealing times may be used and depend upon the particular ceramic dielectric composition and substrate. The selection of such annealing time is within the ability of those skilled in the art. A desirable annealing condition is 650° C. for approximately 15 minutes. Such annealing may be performed in a variety of atmospheres such as air or inert atmospheres such as nitrogen and argon. The film may optionally be further annealed to improve the film's crystallinity. This optional step may involve heating the film such as at a rate of 200° C./hr in a suitable atmosphere to a final annealing temperature of 600 to 900° C., until the desired crystallinity is achieved. Alternatively, the film may be annealed using rapid thermal annealing (“RTA”) techniques, which are well known to those skilled in the art.

Preferred as the titanium alkoxide is titanium isopropoxide. The “barium precursor” may be selected from a variety of barium compounds such as barium carboxylates and the reaction product of a glycol and barium oxide. Exemplary barium carboxylates include, without limitation, barium formate, barium acetate, and barium propionate. Typical glycols are ethylene glycol and propylene glycol. The glycol-barium oxide reaction product is typically diluted with an alcohol prior to the addition of the titanium alkoxide. The “strontium precursor” may be any suitable strontium compound such as strontium carboxylates such as strontium formate, strontium acetate and strontium propionate. Suitable alcohols for use as diluents include, without limitation, ethanol, isopropyl alcohol, methanol, butanol and pentanol.

BST may be prepared as follows, although other suitable preparations may also be used. Barium acetate and strontium acetate are dissolved in a solution of lactic acid and water. A chelating agent is added to the solution and the solution heated to reflux. A suitable solvent is then added and water is distilled off to provide a barium/strontium (“Ba/Sr”) solution. In a separate reaction vessel, titanium isopropoxide is stirred with the chelating agent and the solvent to provide a titanium (“Ti”) solution. The Ti solution is combined with the Ba/Sr solution and the mixture is heated to reflux. The reaction mixture is next diluted to volume with the solvent and the mixture, a BST sol, is ready for coating of the substrate, such as by spin-coating or meniscus coating.

A wide variety of dielectric dopants may be used in the present invention as long as they provide a layer of bulk dielectric material having a positive topography. The dopants are selected such that they have a dielectric constant that is at least ½ the value of the dielectric constant of the bulk dielectric material. Preferably, the dopant has a dielectric constant that is substantially the same as or greater than the bulk dielectric material. By “substantially the same dielectric constant” is meant that the dopants have a dielectric constant that is within 25% (i.e., +25%) of the dielectric constant of the bulk dielectric material. In one embodiment, the dopant has a dielectric constant that is within 10% (i.e., ±10%) of the dielectric constant of the bulk material and preferably within 5%. In another embodiment, the dopant and the bulk dielectric material have a substantially similar coefficient of thermal expansion (“CTE”). By “substantially similar CTE” it is meant that the CTE of the dopant is ±25% of the CTE of the bulk dielectric material. In one embodiment, the dielectric constant of the dopant is not less than the dielectric constant of the bulk dielectric material.

The present dopants are typically particles of dielectric material having a mean size (such as diameter) of 10 nm or greater. Typically, the dopants have a size of 20 nm or greater, more typically 25 nm or greater and still more typically 50 nm or greater. The practical upper limit of the size of the dopant is equal to the thickness of the particular dielectric layer. More typically, the size of the dopant is from 75 to 150% of the thickness of the dielectric material layer. In one embodiment, the size of the dopant is up to 300 nm. Typically, the size of the dopant is up to 250 nm, and more typically up to 200 nm. A useful dopant size range is from 10 to 300 nm, and typically from 10 to 250 nm. Dopant particles may be of any suitable shape, such as, but not limited to, granules, spheres, rods, tori, cones, pyramids, crescents, discs, eggs, needles and cigars. Such dopant particles may be isolated particles or may be agglomerates.

Exemplary dielectric materials used as dopants are any of the dielectric materials described above. In one embodiment, the dopant and the bulk dielectric material have the same composition. In general, when the dopant is a ceramic, such dopant is pre-fired, i.e. such dopant already possess the desired crystallinity prior to any annealing of the bulk dielectric. Such dopants are generally commercially available, such as from Advanced Nano Technologies (Welshpool, Australia), or may be prepared by a variety of means known in the art, such as by sol-gel techniques and CCVD techniques.

When sol-gel processes are used to deposit the capacitor dielectric layers, it is preferred that the dopant is added to the dielectric material sol prior to film deposition. When vapor phase deposition methods are used, it is preferred that the dopant is co-deposited with the bulk dielectric material. It is preferred that the dopant-containing dielectric layers of the present invention are deposited by incorporation into sol-gel precursors and deposited on the substrate by a suitable means (sol-gel processes).

Dopants are present in the bulk dielectric material in an amount sufficient to provide a positive topography when a film of the bulk dielectric material is formed. Such positive topography provides good adhesion to a subsequently applied electrode. The minimum amount of dopant necessary will depend upon the particular dopant size, the thickness of the bulk dielectric material layer and the conductive material layer to be deposited. Such minimum amounts are well within the ability of those skilled in the art. Typically, the amount of the dopant in the bulk dielectric material may range from 5 to 90% by volume, more typically from 15 to 85% by volume and still more typically from 25 to 85% by volume.

Such doped dielectric layers of the capacitor dielectric structure provide increased adhesion for subsequently applied, or plated electrodes. Such electrodes include a conductive material and may also include one or more of a barrier layer and a catalytic layer. As used herein, the term “barrier layer” refers to any layer that prevents or retards oxidation of a conductive material layer or in the case of a copper electrode prevents migration of the copper into the ceramic dielectric. Exemplary barrier layers include, without limitation, nickel, nickel alloys such as nickel-phosphorus, nickel-copper and nickel-chromium, tungsten, titanium, titanium-nitride, tantalum, and tantalum-nitride. “Catalytic layers” refer to layers that catalytically promote electrode formation, such as layers that catalytically promote electroless metal deposition or electroplating. Exemplary conductive materials include, but are not limited to, conductive polymers, metals such as copper, silver, gold, aluminum, platinum, palladium, nickel, tin, lead, and alloys of any of these, and metal oxides. Suitable alloys include tin-lead, tin-copper, tin-bismuth, tin-silver, and tin-silver-copper, as well as alloys containing one or more of bismuth, indium and antimony as alloying metals. Suitable conductive polymers include, metal filled polymers such as copper-filled polymers and silver-filled polymers, polyacetylenes, polyanilines, polypyrroles, polythiophenes, and graphite. Other conductive materials may also be used. Electrodes useful in the present invention may contain more than one conductive material layer. For example, an electrode useful in the present capacitors may include a layer of copper and a layer of silver. Other combinations of conductive materials may suitably be employed. The effective area of the top, bottom or both top and bottom electrodes is increased by the surface area of the dopant particles that are in electrical contact with such electrodes.

In general, the dielectric structures of the present invention are formed by disposing one or more layers of dielectric materials on a substrate, which is typically conductive. Such conductive substrate functions as the bottom electrode of the present capacitors. Such conductive substrates may include any of the conductive materials described above. Particularly suitable conductive substrates are metal foils, such as copper foil, silver foil, and gold foil. Such foils may optionally include one or more coatings such as release layers, adhesion improving layers and/or barrier layers. For example, copper foil may by nickel-coated.

In an alternate embodiment, the present dielectric structures may be formed on a releasable substrate, which need not be conductive. Suitable releasable substrates include polymer sheets and releasable metal foils. For example, metal foils may be made releasable by the use of a release layer between the metal foil and the dielectric material layer. Such release layers, which may include certain metal oxides, are well known in the art. After formation of the desired dielectric structure on such releasable substrate, an electrode is formed on the exposed surface of the top dielectric layer. The dielectric structure is then removed from the releasable substrate and an electrode is formed on the exposed surface of the bottom dielectric layer. In such a structure, both the top and bottom dielectric material layers may contain a dopant.

The dielectric structures of the present invention are useful in forming capacitors. Such dielectric structures may contain one or more capacitor dielectric layers. When two or more dielectric layers are used in the present dielectric structures, a dielectric layer adjacent an electrode, i.e. a dielectric layer in ohmic contact with an electrode, typically contains a dielectric dopant in an amount sufficient to provide a positive topography on the surface of the layer in contact with the electrode. In one embodiment, each dielectric layer adjacent an electrode contains a dielectric dopant. When three or more dielectric layers are used, one or both dielectric layers adjacent an electrode contain a dielectric dopant. In dielectric structures having three or more dielectric layers, the dielectric layers that are not adjacent an electrode do not need to, but may optionally, contain a dopant. Dielectric structures having a plurality of dielectric layers allows for the fabrication of a dielectric structure having a tailored overall dielectric constant.

FIG. 1A illustrates a multilayer dielectric structure according to the present invention having one dielectric layer containing a dopant. Multilayer dielectric stack 2 having individual dielectric layers 2a, 2b and 2c is disposed on conductive substrate 1, such as a nickel-coated copper foil. Top dielectric layer 3 having dopant 4 is disposed on the surface of dielectric stack 2. In one embodiment, each of dielectric layers 2a, 2b, 2c and 3 is a layer of BST. In a further embodiment, dopant 4 is also BST. Top dielectric layer 3 has a positive topography. To form a capacitor, an electrode (not shown) is provided on the surface of top dielectric layer 3. FIG. 1B illustrates a multilayer dielectric structure similar to that illustrated in FIG. 1A, except that dielectric layer 2a also contains dopant 4.

In one embodiment, the present invention provides a dielectric structure including a layer of bulk dielectric material disposed on a conductive substrate, wherein the bulk dielectric material includes a dopant and wherein the bulk dielectric material has a dielectric constant ≧10. The bulk dielectric material is in ohmic contact with the conductive substrate. Preferably, such bulk dielectric material is a ceramic. In a further embodiment, the conductive substrate is a metal foil. In still a further embodiment, the dopant has substantially the same dielectric constant as the bulk dielectric material. In yet another embodiment, the dopant and the bulk dielectric material have substantially the same CTE.

When multiple dielectric layers are used, each of the dielectric layers may be the same or different. In one embodiment, it is preferred that each dielectric layer includes the same dielectric materials. In an alternate embodiment, different dielectric materials are used to form the various dielectric layers. An example of a suitable combination of different ceramic dielectric materials are alternating layers of one or more of alumina, zirconia, barium-strontium-titanate, barium-titanate, lead-zirconium-titanate, and lead-lanthanum-zirconia-titanate, either by themselves or in combination with one or more other dielectric layers.

In one embodiment, the present dopant-containing dielectric layer may be used as the topmost layer in a dielectric stack to provide a subsequently deposited electrode having good adhesion. “Dielectric stack” means two or more dielectric layers in intimate contact. In this embodiment, the layers under the dopant-containing dielectric layer may be deposited by any suitable means, such as, but not limited to, sol-gel techniques such as by meniscus coating and spin-coating, CVD, CCVD, CACCVD or any combination of these. Such dielectric layers under the dopant-containing dielectric layer may be composed of any suitable dielectric material which may be the same as, or different from, the dielectric material used in the dopant-containing dielectric layer.

The overall thickness of the dielectric structure depends upon the capacitor dielectric material selected as well as the total capacitance desired. In multilayer dielectric structures, the dielectric layers may be of uniform thickness or varying thickness. Such structures may consist of many thin layers, one or more thick layers or a mixture of thick and thin layers. Such selections are well within the ability of those skilled in the art. Exemplary dielectric layers may have a thickness of 10 nm to 100 μm.

Preferably, the thickness of the dopant-containing dielectric layer is <50% of the total thickness of the dielectric structure. It is further preferred that the thickness of the dopant-containing dielectric layer is <40%, more preferably <30% and still more preferably <25% of the total thickness of the dielectric structure.

When a ceramic dielectric structure is used, the entire multilayer dielectric structure may be heated (annealed) to provide the dielectric structure having the desired crystal structure. In an alternate embodiment, the non-dopant-containing dielectric gel layers (formed by sol-gel techniques) are first annealed to form the desired crystallinity, followed by deposition of the dielectric dopant-containing sol. The dopant-containing sol is then heated to form the gel and then annealed to provide the desired crystallinity.

After annealing, a dielectric structure prepared from multiple layers of dried ceramic gels of may or may not retain its multilayer structure, i.e. such annealed ceramic dielectric structure may show a single dielectric layer. The present dielectric structures have a dopant-containing region and a non-dopant-containing region, the dopant-containing region being at a surface of the dielectric structure and forming a positive topography at the surface. Alternatively, the annealing of a multilayer dielectric structure composed of dried ceramic gels where both the top and bottom layers contain a dielectric dopant provides a dielectric structure having a first dopant-containing region, a second dopant-containing region and a non-dopant-containing region, the first and second dopant containing regions being at opposite surfaces of the dielectric structure and the non-dopant-containing region being disposed between the first and second-dopant containing regions.

FIG. 1C illustrates a dielectric structure having dielectric layer 5 disposed on conductive substrate 1, dielectric layer 5 having non-dopant containing region 5a and dopant-containing region 5b having dopant 4, dopant-containing region 5b being at a surface of dielectric layer 5 opposite conductive substrate 1. FIG. 1D illustrates a dielectric structure having dielectric layer 5 disposed on conductive substrate 1, dielectric layer 5 having non-dopant containing region 5a, first dopant-containing region 5b having dopant 4 and second-dopant containing region 5c adjacent conductive substrate 1.

Accordingly, the present invention provides a capacitor including a first electrode, a second electrode and a capacitor dielectric disposed between the first and second electrodes, the capacitor dielectric having a non-dopant containing region and a dopant-containing region, where the dopant-containing region is adjacent the first electrode. In such capacitor, the capacitor dielectric may optionally have a second dopant-containing region which is adjacent the second electrode, with the non-dopant-containing region being disposed between the first and second dopant-containing regions. In one embodiment, the capacitor dielectric is a ceramic.

In another embodiment, the capacitor dielectric surfaces may be further textured to still further improve adhesion of an electrode. Such further texturing may be achieved by a variety of means, including, but not limited to, laser structuring, use of removable porogens, chemical etching, and mechanical means such as physical abrasion. The removable porogens may be polymers such as polymeric particles, linear polymers, star polymers or dendritic polymers, or may be monomers or polymers that are co-polymerized with a dielectric monomer to form a block copolymer having a labile (removable) component. In an alternative embodiment, the porogen may be pre-polymerized or pre-reacted with the dielectric precursor to form the sol which may be monomeric, oligomeric or polymeric. Such pre-polymerized material is then annealed to form a dielectric layer. Suitable porogens are those disclosed in, for example, U.S. Pat. No. 6,271,273 (You et al.), U.S. Pat. No. 5,895,263 (Carter et al.) and U.S. Pat. No. 6,420,441 (Allen et al.). The use of such porogens in forming a textured capacitor dielectric are disclosed in U.S. Pat. No. 6,819,540 (Allen et al.). Methods that provide a suitably textured surface while providing control of the resulting dielectric constant are preferred.

Laser structuring of the dielectric surface may be by any laser structuring or ablation methods known in the art. In such methods, the surface of the dielectric stack is subjected to laser structuring, such as laser ablation, prior to the deposition of an electrode (metallization) layer. Such laser ablation is typically computer controlled, thus allowing removal of precise amounts of capacitor dielectric material in a predetermined pattern. Exemplary patterns include, without limitation, grooves, dimples, ripples, cross-hatching, nooks and crannies.

The present dielectric structures having a dielectric layer containing a dopant may be metallized (to form an electrode) by a variety of methods, including, without limitation, electroless plating, chemical vapor deposition, sputtering, evaporation, physical vapor deposition, electrolytic plating, and immersion plating. Electroless plating may suitably be accomplished by a variety of known methods. Suitable metals that can be electrolessly plated include, but are not limited to, copper, gold, silver, nickel, palladium, tin, lead and alloys thereof. Immersion plating may be accomplished by a variety of know methods. Gold, silver, tin and lead may suitably be deposited by immersion plating.

Electrolytic plating may be accomplished by a variety of known methods. Exemplary metals that can be deposited electrolytically include, but are not limited to, copper, gold, silver, nickel, palladium, tin, tin-lead, tin-silver, tin-copper, and tin-bismuth. Prior to electrolytic plating, the surface of the dopant-containing dielectric layer is made sufficiently conductive to provide for electroplating of the desired conductive material. The dielectric layer may be made conductive by electrolessly depositing a metal layer, depositing a conductive polymer, depositing a conductive paste, depositing a conductive barrier layer, or by another suitable method known to those skilled in the art.

Those skilled in the art will appreciate that additional layers of conductive material may be deposited on a first conductive material. Such additional conductive layers may be the same or different from the first conductive layer. The additional conductive layers may be deposited electrolessly, electrolytically, by immersion plating, by chemical vapor deposition, by physical vapor deposition, by CACCVD, by CCVD and by other suitable means. For example, when the conductive layer is deposited by electroless plating, such electroless deposition may be subsequently electrolytically plated to build up a thicker metal deposit. Such subsequently electrolytic deposited metal may be the same as or different from the electrolessly deposited metal.

The present invention provides a method of improving the adhesion of electrodes to a dielectric layer including the steps of depositing on a substrate a layer of a bulk ceramic dielectric material including a dielectric dopant in an amount sufficient to provide positive topography in a surface of the layer, and plating an electrode on the surface of dielectric layer.

One use of the capacitors of the present invention is as embedded capacitors in laminated printed circuit boards. Such capacitors are embedded in a laminate dielectric during the manufacture of laminated printed circuit boards. The laminate dielectrics are typically organic polymers such as epoxies, polyimides, fiber reinforced epoxies and other organic polymers used as dielectrics in the manufacture of printed circuit boards. In general, laminate dielectrics have a dielectric constant ≦6, and typically have a dielectric constant in the range of 3 to 6. The present capacitors may be embedded by a variety of means known in the art, such as those disclosed in U.S. Pat. No. 5,155,655 (Howard et al.).

FIGS. 2A-C illustrate one method of forming an embeddable capacitor of the invention. Capacitor dielectric layer 25, having a dopant-containing region, not shown, is coated on conductive substrate 20, such as by meniscus coating. When dielectric layer 25 is composed of ceramic, such as BST, it typically includes deposition of multiple layers of BST precursor (not shown), at least one of which adjacent an electrode contains dielectric dopant (not shown). When conductive substrate 20 is a coated foil such as nickel-coated copper foil, it contains a copper layer 20a having nickel layers 20b and 20c disposed on opposite major surfaces of copper layer 20a. It will be appreciated the layers 20b and 20c may also include additional layers of materials or alternate layers of materials such as nickel alloys, such as nickel-chromium and nickel-phosphorus. After annealing, conductive substrate 20 is typically laminated to a polymeric laminate dielectric, 30, as shown in FIG. 2B. Next, electrode 27 is provided to the surface of capacitor dielectric layer 25, which has positive topography (not shown), see FIG. 2C. Electrode 27 may be formed by any suitable means, such as by electroless plating followed by electrolytic plating. In one embodiment, electrode 27 includes first layer 27a such as an electroless nickel layer and second layer 27b such as an electroplated copper layer.

Accordingly, the present invention provides a method of manufacturing a multilayer laminated printed circuit board including the step of embedding a capacitance material in one or more layers of the multilayer laminated printed circuit board, wherein the embedded capacitance material includes a dielectric structure including a dopant-containing region and a non-dopant-containing region, wherein the dopant-containing region is adjacent a conductive substrate and in ohmic contact with the conductive substrate. In an alternate embodiment, the present dielectric structures are useful in the formation of capacitors in the manufacture of, without limitation, integrated circuits, chip capacitors, chip packages, multichip modules, and flexible circuits.

Prior to embedding the present capacitors in an electronic device, such as a printed circuit board, they may be etched to form discrete capacitors, or alternatively, used as a sheet to form a shared capacitor. The formation of embedded discrete capacitors is illustrated in FIGS. 3A-3H. Capacitor 35 having bottom electrode (nickel-coated copper foil) 20, capacitor dielectric layer 25, such as BST, having a dopant-containing region providing positive topography at a surface of the dielectric layer (not shown), and top electrode (copper plated electroless nickel) 27 on polymeric laminate dielectric 30 is provided, see FIG. 3A. On top electrode 27 is disposed a photoresist (either dry film or liquid, such as SN 35 available from Rohm and Haas Electronic Materials, Marlborough, Mass.), the photoresist is imaged at the appropriate wavelength and developed to provide patterned photoresist 50, as shown in FIG. 3B, which exposes a portion of top electrode 27 bared of photoresist. Next, the top electrode is etched, such as with 2N HCl/10% CuCl₂, which removes areas of the top electrode bared of photoresist. Patterned photoresist 50 is then stripped to provide a capacitor having patterned top electrode 28 and exposed areas of capacitor dielectric layer 25, as shown in FIG. 3C. A second coating of photoresist is applied over the patterned top electrode. This photoresist is imaged at the appropriate wavelength and developed to provide patterned photoresist 55, as shown in FIG. 3D, where patterned photoresist 55 covers patterned top electrode 28 and a portion of capacitor dielectric layer 25. Exposed portions of capacitor dielectric layer 25 are next removed, such as by etching with an appropriate ceramic etch, to provide the structure shown in FIG. 3E having patterned top electrode 28, patterned capacitor dielectric layer 26, and exposed portions of bottom electrode 20. A third coating of photoresist is applied over the patterned top electrode, the patterned capacitor dielectric layer and a portion of the bottom electrode. This photoresist is imaged at the appropriate wavelength and developed to provide patterned photoresist 60, as shown in FIG. 3F, where patterned photoresist 60 covers patterned top electrode 28, patterned capacitor dielectric layer 26 and a portion of bottom electrode 20. Areas of the bottom electrode bared of photoresist are then etched, such as with 2N HCl/10% CuCl₂, and patterned photoresist 60 is then removed to provide discrete capacitor 40 on polymeric laminate dielectric 30 as shown in FIG. 3G. Next, discrete capacitor 40 is laminated to second polymeric laminate dielectric 45 which embeds discrete capacitor 40.

After a discrete capacitor is embedded in a laminate dielectric, contacts are formed. FIG. 4A illustrates discrete resistor 75 disposed on polymeric laminate dielectric 70 and embedded in polymeric laminate dielectric 80. Polymeric laminate dielectric 80 may or may not be photoimageable. Vias are next provided in polymeric laminate dielectric 80. When the polymeric laminate dielectric is photoimageable, such vias may be formed using photoimaging techniques. Such vias may also be formed by drilling, such as laser drilling using a CO₂, YAG or other suitable laser. FIG. 4B illustrates an embedded discrete capacitor having first via 85a and second via 86a. First via 85a exposes patterned top electrode 28 and second via 86a exposes patterned bottom electrode 21. First contact 85b and second contact 86b are then formed in first via 85a and second via 86a, respectively, as shown in FIG. 4C. Such contacts may be formed by any suitable method, such as electroless plating. Alternate first contact 85c and alternate second contact 86c are shown in FIG. 4D. Alternate contacts 85c and 86c may be formed by any suitable method, such as by electroless plating, electroplating, or a combination of electroless plating and electroplating. A suitable electroplating process for forming the alternate contacts is the CUPULSE plating process (available from Rohm and Haas Electronic Materials).

The following examples are expected to illustrate further various aspects of the present invention.

### EXAMPLE 1

Barium acetate, Ba(CH₃COO)₂, (1 mol) is dissolved in a mixed solution of 20 mol ethanol, 25 mol acetic acid, and 1 mol glycerol, and then the solution is stirred for 2 hr. After stirring, 1 mol of Ti[O(CH₂)₃CH₃]₄ is added to the solution, followed by stirring for another 2 hr to prepare a barium titanate sol.

A sample of this sol is spin coated on a conductive copper-containing substrate at 2000 rpm for 30 sec. After the solution is spin coated, the sample is annealed at 170° C. for 1 hr in a nitrogen-gas atmosphere, followed by two steps of successive annealing of 400° C. for 1 hr and 700° C. for 1 hr in air. The thickness of the annealed dielectric sample prepared using this procedure is ˜100 nm.

To another sample of the sol is added particles of barium titanate (BaTiO₃) as a dielectric dopant in an amount sufficient to provide 40% by volume, based on the total volume of the sol. The dopant-containing sol is then applied to the dielectric surface of the annealed dielectric sample using the conditions disclosed above. The sample is then processed at 400° C. for 1 hr to form the gel. Final phase transformation to the perovskite crystal structure is carried out at 700° C. A dielectric structure having a top dielectric layer containing barium titanate as the dielectric dopant and having a positive topography is expected.

### EXAMPLE 2

The dielectric structure of Example 1 is subjected to a conventional electroless nickel plating bath to deposit a nickel electrode on the dielectric dopant-containing dielectric layer. The electroless nickel plated dielectric is next subjected to a conventional nickel electroplating bath to increase the thickness of the nickel deposit.

### EXAMPLE 3

The procedure of Example 2 is repeated except that the electrolessly nickel plated dielectric is subjected to a conventional acid copper electroplating bath to deposit a layer of copper on the electroless nickel layer.

### EXAMPLE 4

The procedure of Example 1 is repeated except that the dopant is present in an amount of 48% by volume.

### EXAMPLE 5

The procedure of Example 1 is repeated except that the dielectric dopant is barium strontium titanate and is present in an amount of 35% by volume.

### EXAMPLE 6

The procedure of Example 5 is repeated except that the dopant is present in an amount of 45% by volume.

### EXAMPLE 7

The procedure of Example 5 is repeated except that the dopant is present in an amount of 42% by volume.

### EXAMPLE 8

Barium acetate, Ba(CH₃COO)₂, (1 mol) and strontium acetate, Sr(CH₃COO)₂, (1 mol) are dissolved in a mixed solution of lactic acid (5 mol) and water (5 mol). After dissolution, 7 mol diethanolamine are added to the solution and the mixture is then refluxed for 2 hours. Next, 15 mol of 1-butanol are added and the solution is distilled to drive off the water and provide a barium/strontium stock solution.

A titanium stock solution is prepared in a separate reaction vessel by mixing titanium isopropoxide (2 mol), diethanolamine (7 mol) and 1-butanol (7 mol). This titanium stock solution is then added to the barium/strontium stock solution and the mixture is refluxed for 2 hours to prepare a BST sol. This sol is then diluted with 1-butanol to provide the desired concentration and viscosity for meniscus coating. The sol is divided into 2 portions. Portion 1 contained only the sol. Portion 2 was combined with BST particles (40% by volume). The particles are pre-fired ceramic particles.

A piece of nickel-coated copper foil (ca. 45 cm×60 cm) is placed on a vacuum chuck of a meniscus coater. The chuck is inverted and the foil is placed in the coating position. The BST sol (Portion 1) is loaded into coating reservoir 1. The sol flows out the slot on the top surface of the applicator bar forming a meniscus. The nickel-coated copper foil contacts the meniscus and the applicator bar then moves along the length of the copper foil depositing a BST coating. The vacuum chuck is then heated to partially dry the BST coating. The foil is then passed through a conveyorized furnace (450° C./15 min) to volatilize the organic components from the BST film. The foil is then again placed on the vacuum chuck and the coating process repeated as needed to deposit the desired number of layers of BST.

After the desired number of BST gel coating layers (e.g. 2 layers) are deposited, Portion 2 of the sol, which contains the BST particles, is loaded into a second meniscus coating reservoir. A coating of the BST particle-doped BST sol is deposited on the BST gel coating using the coating process described above. The vacuum chuck is then heated to partially dry the film. Next, the foil is passed through the conveyorized furnace (450° C./15 min) to volatilize the organic components from the BST-doped BST gel coating.

The coating layers are then annealed at 650° C. in air to provide a BST perovskite dielectric film having a BST-dopant containing region and a non-dopant-containing region, the non-dopant-containing region being adjacent the nickel-coated copper foil. A BST perovskite dielectric film having positive topography on the surface of the dielectric film opposite the nickel coated copper is expected.

### EXAMPLE 9

The dielectric structure of Example 8 is subjected to a conventional electroless nickel plating bath to deposit a nickel electrode on the BST dopant-containing BST dielectric layer. The electroless nickel plated dielectric is next subjected to a conventional acid copper electroplating bath to deposit a layer of copper on the electroless nickel layer.

### EXAMPLE 10

The dielectric structure of Example 8 is subjected to a conventional electroless nickel plating bath to deposit a nickel conductive layer on the BST dopant-containing BST dielectric layer. The nickel plated dielectric is next subjected to a conventional nickel electroplating bath to increase the thickness of the nickel deposit.

### EXAMPLE 11

The procedure of Example 8 is repeated except that the BST dopant is present in an amount of 65% by volume.

### EXAMPLE 12

The procedure of Example 8 is repeated except that the dopant is barium titanate (“BT”) particles and the BT particles are present in an amount of 18% by volume.

### EXAMPLE 13

The dielectric structure from Example 12 is contacted with a conventional electroless copper plating bath to deposit a layer of copper on the BT dopant-containing dielectric layer.

### EXAMPLE 14

The procedure of Example 8 is repeated except that the BST dopant is present in an amount of 52% by volume.

### EXAMPLE 15

A layer of aluminum is deposited on the dielectric structure from Example 14 by sputtering.

### EXAMPLE 16

The procedure of Example 9 is repeated except that nickel plating bath is a conventional nickel-phosphorus plating bath.

### EXAMPLE 17

The procedure of Examples 1 and 8 are repeated using the dopants in the amounts listed in the Table.

| Example | Dopant | % by Volume | Mean Particle Size (nm) |
|---|---|---|---|
| 1 | BT | 22 | 120 |
| 1 | BT | 37 | 140 |
| 1 | BT | 71 | 115 |
| 1 | BST | 49 | 90 |
| 1 | BST | 54 | 160 |
| 8 | BST | 30 | 135 |
| 8 | BST | 65 | 125 |
| 8 | BT | 7 | 145 |
| 8 | BST | 15 | 150 |
| 8 | BST | 26 | 85 |
| 8 | BST | 58 | 130 |

What is claimed is:

1. A dielectric structure comprising a dielectric material layer disposed on a substrate, wherein the dielectric material comprises a dielectric dopant-containing region and a non-dopant-containing region, the dopant-containing region forming a positive topography at a surface of the dielectric structure.

2. The dielectric structure of claim 1 wherein the dielectric dopant has a dielectric constant that is substantially the same as a dielectric constant of the dielectric material.

3. The dielectric structure of claim 1 wherein the dielectric material has a dielectric constant ≧10.

4. The dielectric structure of claim 1 wherein the substrate is a conductive layer.

5. A capacitor comprising a first electrode, a second electrode and a dielectric structure disposed between the electrodes, wherein the dielectric structure comprises a dielectric material comprising a dielectric dopant-containing region and a non-dielectric dopant-containing region, wherein the dielectric dopant-containing region is adjacent the first electrode.

6. The capacitor of claim 5 wherein the dielectric material is chosen from ceramics, metal oxides and combinations thereof.

7. The capacitor of claim 5 wherein the dielectric material and the dopant have substantially the same dielectric constant.

8. The capacitor of claim 5 wherein the dielectric layer and the dopant have substantially the same coefficient of thermal expansion.

9. An electronic device comprising the capacitor of claim 5.

10. A method of forming the dielectric structure of claim 1 comprising the steps of disposing a layer of a first dielectric material on a substrate, disposing a layer of a dielectric dopant-containing dielectric material on the first dielectric material, and annealing the layers of dielectric materials to form the dielectric structure.
